(19) United States
(12) Patent Application Publication
(10) Pub. No.: US 2026/0332001 A1
(43) Pub. Date: Oct. 22, 2026

(54) COOLING SYSTEM FOR A LINEAR ACTUATOR

(71) Applicant: ASML NETHERLANDS B.V., Veldhoven (NL)

(72) Inventors: Nathan Robert FINNEY, Trumbull, CT (US); Stephen ROUX, New Fairfield, CT (US); Enrico ZORDAN, Darien, CT (US); Krijn Frederik BUSTRAAN, Eindhoven (NL); Daniel Nathan BURBANK, Ridgefield, CT (US)

(73) Assignee: ASML NETHERLANDS B.V., Veldhoven (NL)

(21) Appl. No.: 19/119,312

(22) PCT Filed: Oct. 7, 2023
(86) PCT No.: PCT/EP2023/077808

§ 371 Date: Apr. 8, 2025

Related U.S. Application Data
(60) Provisional application No. 63/422,717, filed on Nov. 4, 2022.

(51) Int. Cl. H02K 9/22; H02K 41/03

(52) U.S. Cl. CPC H02K 9/223; H02K 41/031

(57) ABSTRACT

A cooling system for a linear actuator is described. The system includes electrical coils and cooling plates. The electrical coils are configured to be energized to provide an electromagnetic force for the linear actuator. The electrical coils are configured to surround an armature of the linear actuator. The cooling plates are in thermal contact with the electrical coils and configured to cool the electrical coils. Individual cooling plates are configured to surround the armature and are positioned between adjacent individual coils such that the electrical coils and the cooling plates form an alternating series of plates and coils along a length of the armature.

### CROSS-REFERENCE TO RELATED APPLICATIONS

This application claims priority of U.S. application 63/422,717 which was filed on Nov. 4, 2022 and which is incorporated herein in its entirety by reference.

### TECHNICAL FIELD

This description relates generally to a cooling system for a linear actuator.

### BACKGROUND

Linear actuators are known. Multi-phase electromagnetic linear actuators have been used as long stroke actuators in lithography apparatuses, metrology systems, and other devices, for example. A lithography (e.g., projection) apparatus can be used, for example, in the manufacture of integrated circuits (ICs). In such a case, a patterning device (e.g., a mask) may contain or provide a pattern corresponding to an individual layer of the IC (“design layout”), and this pattern can be transferred onto a target portion (e.g. comprising one or more dies) on a substrate (e.g., silicon wafer) that has been coated with a layer of radiation-sensitive material (“resist”), by methods such as irradiating the target portion through the pattern on the patterning device. In general, a single substrate contains a plurality of adjacent target portions to which the pattern is transferred successively by the lithographic projection apparatus, one target portion at a time. In one type of lithographic projection apparatus, the pattern on the entire patterning device is transferred onto one target portion in one operation. Such an apparatus is commonly referred to as a stepper. In an alternative apparatus, commonly referred to as a step-and-scan apparatus, a projection beam scans over the patterning device in a given reference direction (the “scanning” direction) while synchronously moving the substrate parallel or anti-parallel to this reference direction. Different portions of the pattern on the patterning device are transferred to one target portion progressively. Various movements of the lithography apparatus may be facilitated by one or more linear actuators.

### SUMMARY

A cooling system for a linear actuator is described. The cooling system includes wound electrical coils and cooling plates. The electrical coils are configured to be energized to provide an electromagnetic force for the linear actuator. The electrical coils are configured to surround an armature of the linear actuator. The cooling plates are in thermal contact with the electrical coils and configured to cool the electrical coils. Individual cooling plates are configured to surround the armature and are positioned between adjacent individual coils such that the electrical coils and the cooling plates form an alternating series of plates and coils along a length of the armature. Among other advantages, the electrical coils and the cooling plates are configured to be assembled piece by piece, with alternating wound electrical coils and cooling plates coupled to each other to form the cooling system. A generally perpendicular orientation of the electrical coils and the cooling plates relative to the length of the armature, and/or the separate piece by piece nature of electrical coils and the cooling plates, is configured to reduce shear forces on mechanical fasteners and/or adhesives joining any two wound electrical coils and/or cooling plates along the length of the armature compared to a parallel orientation and/or a unitary structure of the plurality of wound electrical coils and the plurality of cooling plates. In addition, for an implementation with a slotless ferromagnetic armature that functions as a backiron, the generally perpendicular orientation of the cooling plates relative to the length of the armature is configured to reduce a distance between magnets of the linear actuator and the ferromagnetic backiron compared to a parallel orientation of the cooling plates. Also, an orientation of the electrical coils and the cooling plates in a plane perpendicular to the length of the armature is configured to resist unwanted motion or deformation of the linear actuator. Other advantages are contemplated.

According to an embodiment, there is provided a system for a linear actuator. The system comprises a plurality of wound electrical coils configured to be energized to provide an electromagnetic force for the linear actuator. The plurality of wound electrical coils is configured to surround an armature of the linear actuator. The system comprises a plurality of cooling plates in thermal contact with the plurality of wound electrical coils and configured to cool the plurality of wound electrical coils. Individual plates of the plurality of cooling plates are configured to surround the armature and are positioned between adjacent individual coils such that the plurality of wound electrical coils and the plurality of cooling plates form an alternating series of plates and coils along a length of the armature.

In some embodiments, the plurality of wound electrical coils and the plurality of cooling plates are configured to be oriented in planes generally perpendicular to the length of the armature.

In some embodiments, the plurality of wound electrical coils and the plurality of cooling plates are configured to be assembled piece by piece, with alternating wound electrical coils and cooling plates coupled to each other to form the cooling system.

In some embodiments, a generally perpendicular orientation of the plurality of wound electrical coils and the plurality of cooling plates relative to the length of the armature, and/or a separate piece by piece nature of the plurality of wound electrical coils and the plurality of cooling plates, is configured to reduce shear forces on mechanical fasteners and/or adhesives joining any two wound electrical coils and/or cooling plates along the length of the armature compared to a parallel orientation and/or a unitary structure of the plurality of wound electrical coils and the plurality of cooling plates.

In some embodiments, a generally perpendicular orientation of the plurality of cooling plates relative to the length of the armature is configured to reduce a distance between magnets of the linear actuator and the ferromagnetic backiron compared to a parallel orientation of the plurality of cooling plates.

In some embodiments, the plurality of cooling plates have generally rectangular cross sections with one or more cooling channels configured to carry coolant formed therein.

In some embodiments, the plurality of cooling plates are configured to be coupled together such that the one or more cooling channels carry the coolant to cool the plurality of wound electrical coils along the length of the armature.

In some embodiments, the plurality of cooling plates comprise regions having one or more cooling channels and/or electrical routing in plane, regions for bus routing in a normal direction, and/or regions for mechanical coupling to the armature, another plate, and/or a coil.

In some embodiments, the plurality of wound electrical coils are configured to be soldered to each other via inner leads routed through a groove in the armature, the location of which can be selected to minimize airgaps in the flux path through the armature, for example.

In some embodiments, the plurality of wound electrical coils comprise outer leads configured to couple with another coil in series, a junction between parallel phases, or to an amplifier.

In some embodiments, the inner leads, the outer leads, and/or the plurality of wound electrical coils are configured such that distributed phase currents are achieved by overlapping windings.

In some embodiments, the inner leads, the outer leads, and/or the plurality of wound electrical coils are configured such that concentrated phase currents are achieved using stacked coils between cooling plates.

In some embodiments, the system further comprises insulation and/or adhesive positioned between the plurality of wound electrical coils and the plurality of cooling plates.

In some embodiments, the insulation comprises Kapton, a ceramic sheet, a nylon sheet, a Teflon sheet, or another corona resistant polyimide. In general, any material that could serve as an electrical insulator between the coil windings and the metal (as one example material) cool plate may comprise the insulation. In some embodiments, the cooling plates themselves may be an insulting ceramic material and there may be some material between the cooling plates and the coil windings configured for thermal coupling.

In some embodiments, coil and/or cooling plate materials may be selected for optimal matching of a coefficient of thermal expansion between layers of the coils and cooling plates along the length of the armature.

In some embodiments, the plurality of wound electrical coils comprise surface wound flat wire coils or toroidal wound coils.

In some embodiments, coil and plate stacks are configured to be mechanically preloaded in a moving direction of the linear actuator to eliminate a need for glue and/or potting between coils and a coil housing to couple the coils to the cool plates during operation, to maintain good thermal contact, and/or for other reasons.

In some embodiments, the system further comprises canning surfaces configured to enclose the plurality of wound electrical coils, the plurality of cooling plates, and the armature.

In some embodiments, the linear actuator is a Lorentz actuator, or a linear actuator with magnetic materials present in its armature, with our without slots or magnetic teeth in the armature.

In some embodiments, the length comprises a portion of, or a full length of the armature.

In some embodiments, the cooling system and the linear actuator form parts of a lithography apparatus or a metrology apparatus configured for a semiconductor manufacturing process, or any other apparatus requiring precision motion at high accelerations.

According to another embodiment, there is provided a cooling method for a linear actuator. The method comprises forming a plurality of wound electrical coils configured to be energized to provide an electromagnetic force for the linear actuator, the plurality of wound electrical coils configured to surround an armature of the linear actuator. The method comprises forming a plurality of cooling plates and positioning them in thermal contact with the plurality of wound electrical coils, the plurality of cooling plates configured to cool the plurality of wound electrical coils, wherein individual plates of the plurality of cooling plates are configured to surround the armature and are positioned between adjacent individual coils such that the plurality of wound electrical coils and the plurality of cooling plates form an alternating series of plates and coils along a length of the armature.

According to another embodiment, there is provided a lithography apparatus configured for a semiconductor manufacturing process. The lithography apparatus comprises a linear actuator and a cooling system for the linear actuator. The cooling system comprises a plurality of wound electrical coils configured to be energized to provide an electromagnetic force for the linear actuator. The plurality of wound electrical coils are configured to surround an armature of the linear actuator. A plurality of cooling plates in thermal contact with the plurality of wound electrical coils are configured to cool the plurality of wound electrical coils. Individual plates of the plurality of cooling plates are configured to surround the armature and are positioned between adjacent individual coils such that the plurality of wound electrical coils and the plurality of cooling plates form an alternating series of plates and coils along a length of the armature.

### BRIEF DESCRIPTION OF THE DRAWINGS

The accompanying drawings, which are incorporated in and constitute a part of the specification, illustrate one or more embodiments and, together with the description, explain these embodiments. Embodiments of the invention will now be described, by way of example only, with reference to the accompanying schematic drawings in which corresponding reference symbols indicate corresponding parts, and in which:

FIG. 1 schematically depicts a lithography apparatus, which may include a linear actuator with the present cooling system, according to an embodiment.

FIG. 2 schematically depicts an embodiment of a lithographic cell or cluster, which may include a linear actuator with the present cooling system in one or more apparatuses of the lithographic cell or cluster, according to an embodiment.

FIG. 3 illustrates an armature with surface wound electrical coils, compared to an armature with racetrack wound coils, according to an embodiment.

FIG. 4 illustrates phase current distribution configurations for a linear actuator, according to an embodiment.

FIG. 5 illustrates example three-phase current distribution configurations with linear actuator magnet tracks, according to an embodiment.

FIG. 6 illustrates a cooling system for a linear actuator, according to an embodiment.

FIG. 7 illustrates how coil and plate stacks are configured to be mechanically preloaded in a moving direction of a linear actuator to eliminate a need for glue and/or potting between coils and a coil housing to couple the coils to the cool plates during operation; and how a generally perpendicular orientation of the plurality of cooling plates relative to the length of the armature is configured to reduce a distance between magnets of the linear actuator and a ferromagnetic backiron compared to a parallel orientation of the cooling plates, according to an embodiment.

FIG. 8 illustrates cooling channels in a cooling plate connected to main inlet/outlet channels traversing a length of the armature and/or a motor unit of a liner actuator, according to an embodiment. Note that the cooling channel(s) may take any path, not necessarily straight paths along the length of the coil windings. Channel paths may be optimized to ensure every wind in the coil overlaps with cooling water at some point, for example.

FIG. 9 illustrates how a plurality of surface wound electrical coils and a plurality of cooling plates are configured to be assembled piece by piece, with alternating surface wound electrical coils and cooling plates coupled to each other to form the cooling system, according to an embodiment.

FIG. 10 illustrates regions of a coil/plate configured for routing electrical connections through volumes between cooling plates and penetrating cooling plates cross sections, according to an embodiment.

FIG. 11 illustrates an example three-phase forcer with a distributed current distribution, according to an embodiment.

FIG. 12 illustrates example three-phase forcers with concentrated and distributed current distributions, according to an embodiment.

FIG. 13 illustrates a cooling method for a linear actuator, according to an embodiment.

### DETAILED DESCRIPTION

Multi-phase electromagnetic linear actuators of two separate types have been used as long stroke actuators in lithography apparatuses, metrology systems, and other devices. For example, Lorentz actuators, linear actuators with magnetic materials present in their armatures with or without slots or magnetic teeth in the armature, and/or other motion systems are used in lithography apparatuses (these may also be known as slotted iron core LPMSMs (Linear Permanent Magnet Synchronous Motors), for example). Higher lithography apparatus stage accelerations are desired. Higher stage accelerations increase productivity of a lithography apparatus, resulting in a lower cost per die (or per microchip).

However, higher stage accelerations cause increased dynamic loading and increased thermal loading in current linear actuators used in lithography apparatuses. The increased dynamic and thermal loading can cause a catastrophic temperature increase in linear actuator coils and/or an overall failure of an actuator motor, increased demand on amplifiers, and, depending on the design, a greater degree of saturation of soft-magnetic materials present in a magnetic circuit of the linear actuator. Increased thermal loading is known to reduce the efficiency or actuators due to the thermal runaway effect (resistance increases at higher temperature, at higher resistance more power is dissipated, thus more heat is generated by the coils which further raises their temperature). Catastrophic failure of the coil windings is widely recognized to occur when the coil temperature exceeds the wire insulation rating. These factors limit an achievable force density (in [N/kg]) by the linear actuator, and therefore limit an achievable peak acceleration of a lithography apparatus stage ([N/kg]=[m/s2]). Three-phase Lorentz actuators, for example, using moving magnets or moving coils are presently used in many lithography apparatuses. Lorentz actuators are sometimes favored because they produce less vibration and produce less prevalent nonlinear behavior compared to other linear actuators. However, Lorentz actuators are relatively inefficient compared to the other linear actuators, requiring more average power from amplifiers.

A new cooling system for a linear actuator is described below. The new cooling system includes wound electrical coils and cooling plates. The electrical coils and cooling plates are configured to surround an armature of the linear actuator, with individual cooling plates positioned between adjacent individual coils such that the electrical coils and the cooling plates form an alternating series of plates and coils along a length of the armature. Advantageously, this design allows the electrical coils and the cooling plates to be assembled piece by piece, with alternating wound electrical coils and cooling plates coupled to each other to form the cooling system. A generally perpendicular orientation of the electrical coils and the cooling plates relative to the length of the armature, and/or the separate piece by piece nature of electrical coils and the cooling plates, is configured to reduce shear forces on mechanical fasteners and/or adhesives joining any two wound electrical coils and/or cooling plates along the length of the armature compared to a parallel orientation and/or a unitary structure of the plurality of wound electrical coils and the plurality of cooling plates (e.g., as in prior linear actuators described above). In addition, the generally perpendicular orientation of the cooling plates relative to the length of the armature is configured to reduce a distance between magnets of the linear actuator and the ferromagnetic backiron compared to a parallel orientation of the cooling plates. Also, an orientation of the electrical coils and the cooling plates in a plane perpendicular to the length of the armature is configured to resist unwanted motion or deformation of the linear actuator. Thus, a linear actuator having the new cooling system described below is more efficient compared to prior linear actuators, requiring reduced average power from amplifiers compared to prior linear actuators. This allows such a linear actuator to achieve a higher force density (limited by coil temperature or amplifier limits) compared to prior linear actuators, and therefore achieve a higher peak acceleration of a lithography apparatus stage.

The following introductory paragraphs describe general lithography system functionality as one of many possible use case examples for the linear actuator(s) described herein. Note that although specific reference may be made in this text to the manufacture of integrated circuits (ICs), it should be understood that the described cooling system has many other possible applications. For example, it may be employed in the manufacture of integrated optical systems, guidance and detection patterns for magnetic domain memories, liquid-crystal display panels, thin-film magnetic heads, etc.

As an introduction, prior to transferring a pattern from a patterning device such as a mask to a substrate, the substrate may undergo various procedures, such as priming, resist coating and a soft bake. After exposure, the substrate may be subjected to other procedures (“post-exposure procedures”), such as a post-exposure bake (PEB), development, a hard bake and measurement and/or other inspection of the transferred pattern. This array of procedures is used as a basis to make an individual layer of a device, e.g., an IC. The substrate may then undergo various processes such as etching, ion-implantation (doping), metallization, oxidation, chemical mechanical polishing, etc., all intended to finish an individual layer of the device. If several layers are required in the device, then the whole procedure, or a variant thereof, is repeated for each layer. Eventually, a device will be present in each target portion on the substrate. These devices are then separated from one another by a technique such as dicing or sawing, and then the individual devices can be mounted on a carrier, connected to pins, etc.

Manufacturing devices, such as semiconductor devices, typically involves processing a substrate (e.g., a semiconductor wafer) using a number of fabrication processes to form various features and multiple layers of the devices. Such layers and features are typically manufactured and processed using, e.g., deposition, lithography, etch, chemical mechanical polishing, ion implantation, and/or other processes. Multiple devices may be fabricated on a plurality of dies on a substrate and then separated into individual devices. This device manufacturing process may be considered a patterning process. A patterning process involves a patterning step, such as optical and/or nanoimprint lithography using a patterning device in a lithographic apparatus, to transfer a pattern on the patterning device to a substrate and typically, but optionally, involves one or more related pattern processing steps, such as resist development by a development apparatus, baking of the substrate using a bake tool, etching using the pattern using an etch apparatus, etc. One or more metrology processes are typically involved in the patterning process. Lithography apparatuses, metrology systems, and other equipment used to fabricate semiconductor devices may use one or more linear actuators having the described cooling system.

Lithography is a step in the manufacturing of device such as ICs, where patterns formed on substrates define functional elements of the devices, such as microprocessors, memory chips, etc. Similar lithographic techniques are also used in the formation of flat panel displays, micro-electro mechanical systems (MEMS) and other devices.

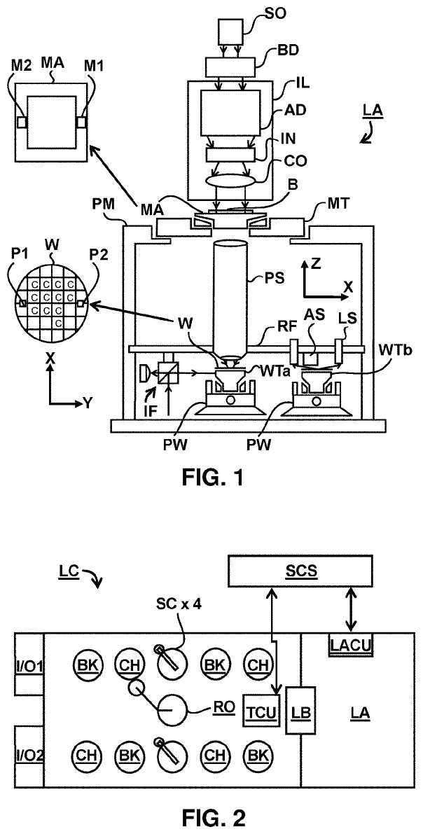

FIG. 1 schematically depicts an embodiment of a lithographic apparatus LA that may include and/or be associated with one or more linear actuators and corresponding cooling systems. The apparatus comprises: an illumination system (illuminator) IL configured to condition a radiation beam B (e.g. UV radiation, DUV radiation, or EUV radiation); a support structure (e.g. a mask table) MT constructed to support a patterning device (e.g. a mask) MA and connected to a first positioner PM configured to accurately position the patterning device in accordance with certain parameters; a substrate table (e.g. a wafer table) WT (e.g., WTa, WTb or both) configured to hold a substrate (e.g. a resist-coated wafer) W and coupled to a second positioner PW configured to accurately position the substrate in accordance with certain parameters; and a projection system (e.g. a refractive projection lens system) PS configured to project a pattern imparted to the radiation beam B by patterning device MA onto a target portion C (e.g. comprising one or more dies and often referred to as fields) of the substrate W. The projection system is supported on a reference frame (RF). As depicted, the apparatus is of a transmissive type (e.g. employing a transmissive mask). Alternatively, the apparatus may be of a reflective type (e.g. employing a programmable mirror array of a type as referred to above, or employing a reflective mask).

The illuminator IL receives a beam of radiation from a radiation source SO. The source and the lithographic apparatus may be separate entities, for example when the source is an excimer laser. In such cases, the source is not considered to form part of the lithographic apparatus and the radiation beam is passed from the source SO to the illuminator IL with the aid of a beam delivery system BD comprising for example suitable directing mirrors and/or a beam expander. In other cases, the source may be an integral part of the apparatus, for example when the source is a mercury lamp. The source SO and the illuminator IL, together with the beam delivery system BD if required, may be referred to as a radiation system.

The illuminator IL may alter the intensity distribution of the beam. The illuminator may be arranged to limit the radial extent of the radiation beam such that the intensity distribution is non-zero within an annular region in a pupil plane of the illuminator IL. Additionally or alternatively, the illuminator IL may be operable to limit the distribution of the beam in the pupil plane such that the intensity distribution is non-zero in a plurality of equally spaced sectors in the pupil plane. The intensity distribution of the radiation beam in a pupil plane of the illuminator IL may be referred to as an illumination mode.

The illuminator IL may comprise adjuster AD configured to adjust the (angular/spatial) intensity distribution of the beam. Generally, at least the outer and/or inner radial extent (commonly referred to as σ-outer and σ-inner, respectively) of the intensity distribution in a pupil plane of the illuminator can be adjusted. The illuminator IL may be operable to vary the angular distribution of the beam. For example, the illuminator may be operable to alter the number, and angular extent, of sectors in the pupil plane wherein the intensity distribution is non-zero. By adjusting the intensity distribution of the beam in the pupil plane of the illuminator, different illumination modes may be achieved. For example, by limiting the radial and angular extent of the intensity distribution in the pupil plane of the illuminator IL, the intensity distribution may have a multi-pole distribution such as, for example, a dipole, quadrupole or hexapole distribution. A desired illumination mode may be obtained, e.g., by inserting an optic which provides that illumination mode into the illuminator IL or using a spatial light modulator.

The illuminator IL may be operable to alter the polarization of the beam and may be operable to adjust the polarization using adjuster AD. The polarization state of the radiation beam across a pupil plane of the illuminator IL may be referred to as a polarization mode. The use of different polarization modes may allow greater contrast to be achieved in the image formed on the substrate W. The radiation beam may be unpolarized. Alternatively, the illuminator may be arranged to linearly polarize the radiation beam. The polarization direction of the radiation beam may vary across a pupil plane of the illuminator IL. The polarization direction of radiation may be different in different regions in the pupil plane of the illuminator IL. The polarization state of the radiation may be chosen in dependence on the illumination mode. For multi-pole illumination modes, the polarization of each pole of the radiation beam may be generally perpendicular to the position vector of that pole in the pupil plane of the illuminator IL. For example, for a dipole illumination mode, the radiation may be linearly polarized in a direction that is substantially perpendicular to a line that bisects the two opposing sectors of the dipole. The radiation beam may be polarized in one of two different orthogonal directions, which may be referred to as X-polarized and Y-polarized states. For a quadrupole illumination mode, the radiation in the sector of each pole may be linearly polarized in a direction that is substantially perpendicular to a line that bisects that sector. This polarization mode may be referred to as XY polarization. Similarly, for a hexapole illumination mode the radiation in the sector of each pole may be linearly polarized in a direction that is substantially perpendicular to a line that bisects that sector. This polarization mode may be referred to as TE polarization.

In addition, the illuminator IL generally comprises various other components, such as an integrator IN and a condenser CO. The illumination system may include various types of optical components, such as refractive, reflective, magnetic, electromagnetic, electrostatic, or other types of optical components, or any combination thereof, for directing, shaping, or controlling radiation. Thus, the illuminator provides a conditioned beam of radiation B, having a desired uniformity and intensity distribution in its cross section.

The support structure MT supports the patterning device in a manner that depends on the orientation of the patterning device, the design of the lithographic apparatus, and other conditions, such as for example whether or not the patterning device is held in a vacuum environment. The support structure may use mechanical, vacuum, electrostatic or other clamping techniques to hold the patterning device. The support structure may be a frame or a table, for example, which may be fixed or movable as required. The support structure may ensure that the patterning device is at a desired position, for example with respect to the projection system.

The lithographic apparatus may be of a type having two (dual stage) or more tables (e.g., two or more substrate tables WTa, WTb, two or more patterning device tables, a substrate table WTa and a table WTb below the projection system without a substrate that is dedicated to, for example, facilitating measurement, and/or cleaning, etc.). In such “multiple stage” machines, the additional tables may be used in parallel, or preparatory steps may be carried out on one or more tables while one or more other tables are being used for exposure. For example, alignment measurements using an alignment sensor AS and/or level (height, tilt, etc.) measurements using a level sensor LS may be made.

In operation of the lithographic apparatus, a radiation beam is conditioned and provided by the illumination system IL. The radiation beam B is incident on the patterning device (e.g., mask) MA, which is held on the support structure (e.g., mask table) MT. Having traversed the patterning device MA, the radiation beam B passes through the projection system PS, which focuses the beam onto a target portion C of the substrate W. With the aid of the second positioner PW and position sensor IF (e.g., an interferometric device, linear encoder, 2-D encoder, or capacitive sensor), the substrate table WT can be moved accurately, e.g. to position different target portions C in the path of the radiation beam B. Similarly, the first positioner PM and another position sensor (which is not explicitly depicted in FIG. 1) can be used to accurately position the patterning device MA with respect to the path of the radiation beam B, e.g. after mechanical retrieval from a mask library, or during a scan. In general, movement of the support structure MT may be realized with the aid of a long-stroke module (coarse positioning) and a short-stroke module (fine positioning), which form part of the first positioner PM. Similarly, movement of the substrate table WT may be realized using a long-stroke module and a short-stroke module, which form part of the second positioner PW. In the case of a stepper (as opposed to a scanner), the support structure MT may be connected to a short-stroke actuator only, or may be fixed. Patterning device MA and substrate W may be aligned using patterning device alignment marks M1, M2 and substrate alignment marks P1, P2. Although the substrate alignment marks as illustrated occupy dedicated target portions, they may be located in spaces between target portions (these are known as scribe-lane alignment marks). Similarly, in situations in which more than one die is provided on the patterning device MA, the patterning device alignment marks may be located between the dies.

The depicted apparatus may be used in at least one of the following modes: 1. In step mode, the support structure MT and the substrate table WT are kept essentially stationary, while a pattern imparted to the radiation beam is projected onto a target portion C at one time (i.e. a single static exposure). The substrate table WT is then shifted in the X and/or Y direction so that a different target portion C can be exposed. In step mode, the maximum size of the exposure field limits the size of the target portion C imaged in a single static exposure. 2. In scan mode, the support structure MT and the substrate table WT are scanned synchronously while a pattern imparted to the radiation beam is projected onto a target portion C (i.e. a single dynamic exposure). The velocity and direction of the substrate table WT relative to the support structure MT may be determined by the (de-) magnification and image reversal characteristics of the projection system PS. In scan mode, the maximum size of the exposure field limits the width (in the non-scanning direction) of the target portion in a single dynamic exposure, whereas the length of the scanning motion determines the height (in the scanning direction) of the target portion. 3. In another mode, the support structure MT is kept essentially stationary holding a programmable patterning device, and the substrate table WT is moved or scanned while a pattern imparted to the radiation beam is projected onto a target portion C. In this mode, generally a pulsed radiation source is employed, and the programmable patterning device is updated as required after each movement of the substrate table WT or in between successive radiation pulses during a scan. This mode of operation can be readily applied to maskless lithography that utilizes programmable patterning device, such as a programmable mirror array of a type as referred to above. Combinations and/or variations on the above-described modes of use or entirely different modes of use may also be employed.

A substrate may be processed, before or after exposure, in for example a track (a tool that typically applies a layer of resist to a substrate and develops the exposed resist) or a metrology or inspection tool. Any or all of these tools may include linear actuators with corresponding cooling systems.

Various patterns on or provided by a patterning device may have different process windows. i.e., a space of processing variables under which a pattern will be produced within specification. Examples of pattern specifications that relate to potential systematic defects include checks for necking, line pull back, line thinning, critical dimension (CD), edge placement, overlapping, resist top loss, resist undercut and/or bridging. The process window of the patterns on a patterning device or an area thereof may be obtained by merging (e.g., overlapping) process windows of each individual pattern. The boundary of the process window of a group of patterns comprises boundaries of process windows of some of the individual patterns. In other words, these individual patterns limit the process window of the group of patterns.

As shown in FIG. 2, the lithographic apparatus LA may form part of a lithographic cell LC, also sometimes referred to a lithocell or cluster, which also includes apparatuses to perform pre-and post-exposure processes on a substrate. Conventionally these include one or more spin coaters SC to deposit one or more resist layers, one or more developers to develop exposed resist, one or more chill plates CH and/or one or more bake plates BK. A substrate handler, or robot, RO picks up one or more substrates from input/output port I/O1, I/O2, moves them between the different process apparatuses and delivers them to the loading bay LB of the lithographic apparatus. These apparatuses, which are often collectively referred to as the track, are under the control of a track control unit TCU which is itself controlled by the supervisory control system SCS, which also controls the lithographic apparatus via lithography control unit LACU. Thus, the different apparatuses can be operated to maximize throughput and processing efficiency.

In order that a substrate that is exposed by the lithographic apparatus is exposed correctly and consistently and/or in order to monitor a part of the patterning process (e.g., a device manufacturing process) that includes at least one pattern transfer step (e.g., an optical lithography step), it is desirable to inspect a substrate or other object to measure or determine one or more properties such as alignment, overlay (which can be, for example, between structures in overlying layers or between structures in a same layer that have been provided separately to the layer by, for example, a double patterning process), line thickness, critical dimension (CD), focus offset, a material property, etc.

The one or more measured parameters may include, for example, alignment, overlay between successive layers formed in or on the patterned substrate, critical dimension (CD) (e.g., critical linewidth) of, for example, features formed in or on the patterned substrate, focus or focus error of an optical lithography step, dose or dose error of an optical lithography step, optical aberrations of an optical lithography step, etc. This measurement may be performed on a target of the product substrate itself and/or on a dedicated metrology target provided on the substrate. The measurement can be performed after-development of a resist but before etching, after-etching, after deposition, and/or at other times.

There are various techniques for making measurements of the structures formed in the patterning process, including the use of a scanning electron microscope, an image-based measurement tool and/or various specialized tools. Any or all of these tools may include linear actuators with corresponding cooling systems. A fast and non-invasive form of specialized metrology tool is one in which a beam of radiation is directed onto a target on the surface of the substrate and properties of the scattered (diffracted/reflected) beam are measured. By evaluating one or more properties of the radiation scattered by the substrate, one or more properties of the substrate can be determined. This may be termed diffraction-based metrology. One such application of this diffraction-based metrology is in the measurement of feature asymmetry within a target. This can be used as a measure of overlay, for example, but other applications are also known. For example, asymmetry can be measured by comparing opposite parts of the diffraction spectrum (for example, comparing the −1st and +1^{st} orders in the diffraction spectrum of a periodic grating).

Metrology results may be provided directly or indirectly to the supervisory control system SCS. If an error is detected, an adjustment may be made to exposure of a subsequent substrate (especially if the inspection can be done soon and fast enough that one or more other substrates of the batch are still to be exposed) and/or to subsequent exposure of the exposed substrate. Also, an already exposed substrate may be stripped and reworked to improve yield, or discarded, thereby avoiding performing further processing on a substrate known to be faulty. In a case where only some target portions of a substrate are faulty, further exposures may be performed only on those target portions which meet specifications.

The present cooling system(s), and/or method(s) may be used as stand-alone tools and/or techniques, and/or or used in conjunction with semiconductor manufacturing apparatuses and/or processes, to enhance the accurate transfer of complex designs to physical wafers. For example, the present cooling system may be part of a linear actuator included the lithography apparatus shown in FIG. 1, included in one or more apparatuses of the lithographic cell shown in FIG. 2, and/or included in other apparatuses (semiconductor or non-semiconductor related). As described above, the present cooling system includes surface wound electrical coils and cooling plates. The electrical coils are configured to be energized to provide an electromagnetic force for the linear actuator. The electrical coils are configured to surround an armature of the linear actuator. The cooling plates are in thermal contact with the electrical coils and configured to cool the electrical coils. Individual cooling plates are configured to surround the armature and are positioned between adjacent individual coils such that the electrical coils and the cooling plates form an alternating series of plates and coils along a length of the armature.

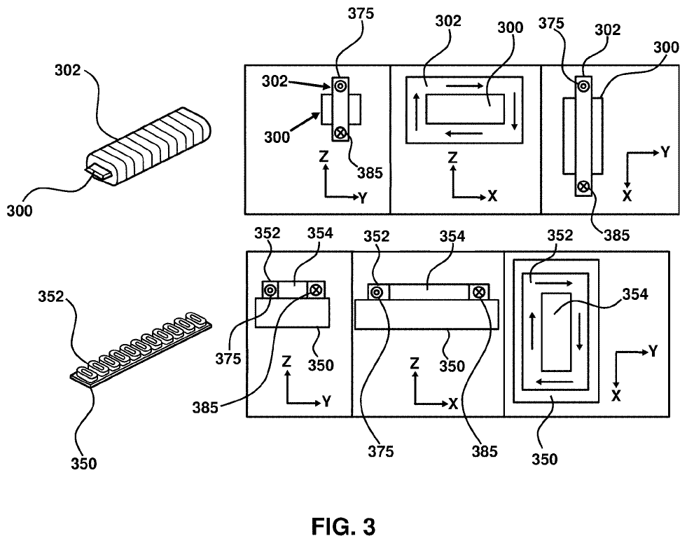

FIG. 3-5 provide base descriptions of various linear actuator related terminology. For example, FIG. 3 illustrates an armature 300 with surface wound electrical coils 302, compared to an armature 350 with racetrack wound coils 352. Surface wound electrical coils 302 comprise coils with windings encircling armature 300 (encircling the y-axis in this example). Racetrack wound coils 352 have windings that lie on a surface of armature 350 (encircling the z-axis in this example). FIG. 3 illustrates racetrack wound coils 352 surrounding a core 354. Core 354 may comprise a soft ferromagnetic material, and/or other materials. In some embodiments, racetrack wound coils 352 and corresponding cores 354 may be coupled to a surface of armature 350 (top plane of armature 350 parallel to the xy-plane in FIG. 3), and/or some other surface (which can then act as an armature providing mechanical support). Dotted circles 375 in FIG. 3 indicate winds or current coming out of the page, with crossed circles 385 indicating winds or current into the page. Armature 300 and/or 350 may comprise a structural member configured to mechanically support surface wound electrical coils 302 or racetrack wound coils 352, cooling plates (described below), and/or other components. Armature 300 and/or 350 may form part of a linear actuator that includes the main current-carrying windings (e.g., coils 302 or 352) and in which electromotive force is induced. Armature 300 and/or 350 may comprise a soft ferromagnetic material and/or other materials, for example.

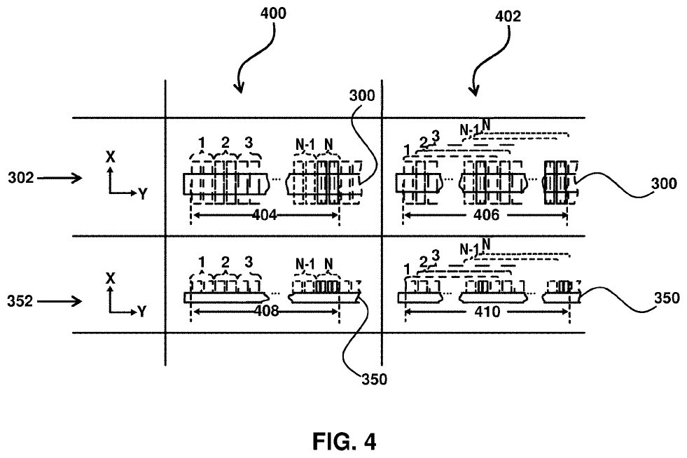

FIG. 4 illustrates phase current distribution configurations for a linear actuator. FIG. 4 illustrates concentrated phase current 400 and distributed phase current 402 (for N phases). FIG. 4 illustrates surface wound coils 302 with armature 300, and racetrack wound coils 352 with armature 350 (shown in a yz plane). FIG. 4 illustrates N-phase coil pitches 404, 406, 408, and 410. For concentrated phase current 400, the current per phase has an adjacent +/−x current direction. For distributed phase current 402, the current per phase has a +/−x current direction that is spatially distributed. Linear actuators in lithography apparatuses may use racetrack wound coils 352 with concentrated phase current 400 as a forcer (lower left box, note coils would be sandwiched between cool plates oriented in the xy-plane). The present cooling system enables both concentrated and distributed winding configurations for surface wound coils (top row of FIG. 4) in linear actuators.

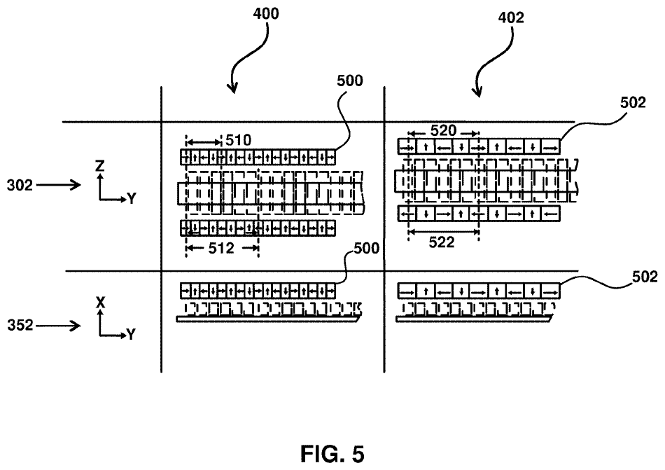

FIG. 5 illustrates example three-phase current distribution configurations with linear actuator magnet tracks 500 and 502. FIG. 5 illustrates concentrated phase current 400 configurations and distributed phase current 402 configurations for surface wound coils 302 with armature 300, and racetrack wound coils 352 with armature 350. Magnet track 500 has a magnet pitch 510 that is not the same as a coil pitch 512 (a 2:1 pitch ratio (coil to magnet)), while magnet track 502 has a magnet pitch 520 that is the same as a coil pitch 522 (a “full pitch” distributed phase current). Note that FIG. 5 is an example only, and many other configurations are possible (e.g., phases per actuator ≥3; pitch ratios other than 1:1 or 2:1; number of polarizations per magnet pitch ≥2 and #4 in Halbach array, etc.). Also, linear actuator motors with surface wound coils are typically double-sided (with two magnet tracks) to make use of both top and bottom current distributions. Surface wound configurations require a 180° phase shift in magnet polarizations between the upper and lower tracks.

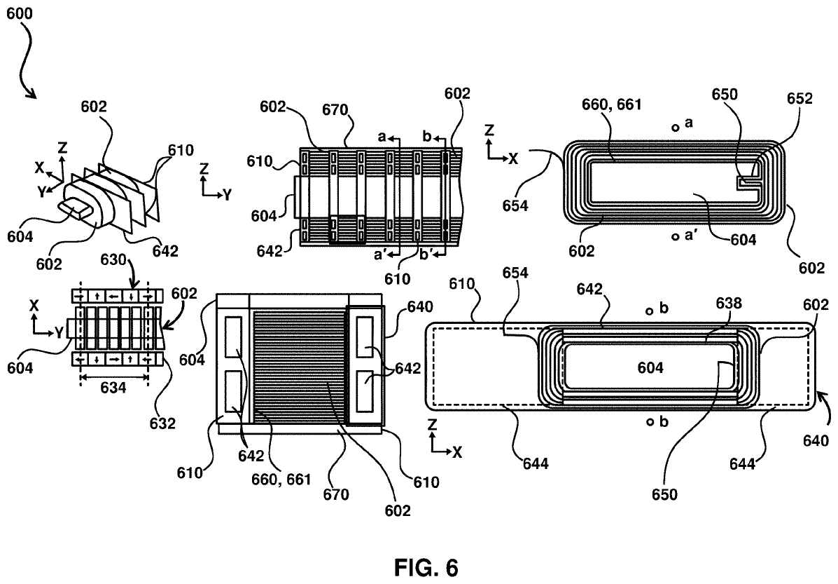

FIG. 6 illustrates a cooling system 600 for a linear actuator, according to an embodiment. The linear actuator may be a Lorentz actuator, a linear actuator with magnetic materials present in the armature with or without slots or magnetic teeth in the armature, and/or other linear actuators. Cooling system 600 and the linear actuator may form parts of a lithography apparatus or a metrology apparatus configured for a semiconductor manufacturing process, for example, and/or may have other applications. Prior linear actuators in such apparatuses typically included coils and/or cool plates oriented ‘horizontally’ (generally parallel to a top or bottom surface of an armature). In contrast, system 600 comprises a cooling system with coils and cooling plates oriented “vertically” (generally perpendicular to the top or bottom surfaces of an armature). Benefits of this orientation include stiff supports for the coils, an additional cooling surface relative to prior linear actuators, and design freedom for routing electrical connections for a wide range of phase current distributions that may be favorable for achieving high force density with reduced force ripple.

System 600 comprises a plurality of surface wound electrical coils 602 configured to be energized to provide an electromagnetic force for the linear actuator. Surface wound electrical coils 602 may be flat wire coils, for example, and/or other coils. Surface wound electrical coils 602 may be formed from copper and/or other materials. The plurality of surface wound electrical coils 602 are configured to surround an armature 604 of the linear actuator. The plurality of surface wound electrical coils 602 may comprise surface wound flat wire coils or toroidal wound coils, for example. FIG. 6 also illustrates magnet tracks 630, 632 of the linear actuator on either side of (above and below) surface wound electrical coils 602 and armature 604. A pitch of magnet tracks 630 and 632 matches a width 634 of a pitch of surface wound electrical coils 602 in this embodiment.

System 600 comprises plurality of cooling plates 610 in thermal contact with the plurality of surface wound electrical coils 602. Cooling plates 610 are coupled 638 to armature 604, surface wound electrical coils 602, and/or other components. This coupling 638 may be thought of as lamination, for example (e.g., laminated cooling plates 610). Cooing plates 610 are configured to be rigidly fastened to armature 604, resulting in mechanically stiff support of the surface wound electrical coils 602 along the drive and normal directions of the linear actuator. Cooling plates 610 are configured to cool the plurality of surface wound electrical coils 602. Individual plates of the plurality of cooling plates 610 are configured to surround armature 604 and are positioned between adjacent individual coils 602 such that the plurality of surface wound electrical coils 602 and the plurality of cooling plates 610 form an alternating series 620 of plates 610 and surface wound electrical coils 602 along a length of armature 604. The length comprises a portion of, or a full length of armature 604, for example. Note that cooling plates 610 are configured to be in thermal contact with the edges of coils 602 (e.g., every wind is in direct contact with a surface of a cooling plate 610).

As shown in FIG. 6, the plurality of cooling plates 610 have generally rectangular cross sections 640 with one or more cooling channels 642 configured to carry coolant formed therein. Note that cooling plates 610 may have any cross sectional shape and/or any number of channels 642 oriented in any configuration that allows them to function as described herein. The plurality of cooling plates 610 are configured to be coupled together such that the one or more cooling channels 642 carry the coolant to cool the plurality of surface wound electrical coils 602 along the length of armature 604. The plurality of cooling plates 610 comprise regions 644 having one or more cooling channels 642 and/or electrical routing in plane, regions for bus routing in a normal direction, and/or regions for mechanical coupling to armature 604, another plate 610, and/or a surface wound electrical coil 602.

In some embodiments, the plurality of surface wound electrical coils 602 are configured to be soldered to each other via inner leads 650 routed through a groove 652 in armature 604, and/or coupled to each other in other ways. An adjacent surface wound electrical coil 602 can have an opposite or same winding direction depending on the configuration. The plurality of surface wound electrical coils 602 also comprise outer leads 654 configured to couple with another surface wound electrical coil 602 in series, a junction between parallel phases, or to an amplifier, for example.

In some embodiments, system 600 comprises insulation 660 and/or adhesive 661 positioned between the plurality of surface wound electrical coils 602 and the plurality of cooling plates 610. Insulation 660 may comprise Kapton, a ceramic sheet, a nylon sheet, a Teflon sheet, any/or any another corona resistant polyimide. In general, any material that could serve as an electrical insulator between the coil windings and the metal (as one example material) cool plate may comprise the insulation. In some embodiments, the cooling plates themselves may be an insulting ceramic material and there may be some material between the cooling plates and the coil windings configured for thermal coupling.

In some embodiments, system 600 comprises a cover and/or canning surfaces 670 configured to enclose the plurality of surface wound electrical coils 602, the plurality of cooling plates 610, armature 604, and/or other components of system 600. Canning surfaces may also provide additional mechanical support for one or more components of system 600. Canning surfaces may be a corrosion resistant material like stainless steel (and also non-magnetic). The canning surface's purpose is to prevent the ferromagnetic material from embrittling due to a chemical reaction. The can could be a welded box or could be deposited in some way, for example.

As shown in FIG. 6, the plurality of surface wound electrical coils 602 and the plurality of cooling plates 610 are configured to be oriented in planes generally perpendicular to the length of armature 604. The plurality of surface wound electrical coils 602 and the plurality of cooling plates 610 are configured to be separated piece by piece components. The generally perpendicular orientation of the plurality of surface wound electrical coils 602 and the plurality of cooling plates 610 relative to the length of armature 604, and/or the separate piece by piece nature of the plurality of surface wound electrical coils 602 and the plurality of cooling plates 610, is configured to reduce shear forces on mechanical fasteners and/or adhesives (e.g., 661) joining any two surface wound electrical coils 602 and/or cooling plates 610 along the length of armature 604 compared to a parallel orientation and/or a unitary structure of the plurality of surface wound electrical coils 602 and the plurality of cooling plates 610. A glue layer may hold the coils in place and/or perform other functions. Functionally the glue layer would go beyond holding the coils in place. It may serve as a viscoelastic coupling between two parts of the system (coils and insulated cool plates) that have different coefficients of thermal expansion (CTE), yet still need to transfer force to one another. The viscoelastic nature of the glue layer allows for mechanical and thermal coupling even with coils and cool plates growing and shrinking by different amounts during force and thermal cycling due to their CTE mismatch. The glue layer can also serve as additional protection against breakdown between the coils and the optionally metallic cool plates by eliminating voids (filling all negative space in the coil/thermal gap volume helps with this). In the instance of optionally including a glue layer for the present system, the benefits of the viscoelastic coupling would still be there beyond simply holding the coils in place. Attempting to capture these benefits would be at the expense of the claimed performance improvements, so would be up to a designer to choose (hence optional).

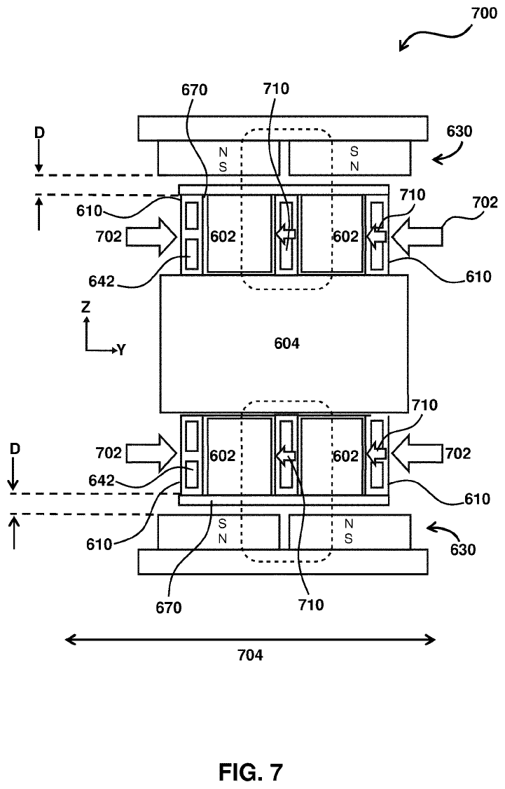

FIG. 7 illustrates how surface wound electrical coil 602 and plate 610 stacks 700 are configured to be mechanically preloaded 702 in a moving direction 704 of a linear actuator to reduce and/or eliminate a need for glue and/or potting between coils 602 and a coil housing (though this may be optionally included in system 600 as shown in FIG. 6) to couple the coils to the cool plates during operation (FIG. 7 shows reaction forces 710). The generally perpendicular orientation of the plurality of cooling plates 610 relative to the length of armature 604 is configured to reduce a distance D between magnet tracks 630 of the linear actuator and the plurality of surface wound electrical coils 602 compared to a parallel orientation of the plurality of cooling plates 610 (as in prior systems that include a laminated stacking of coils and cooling plates).

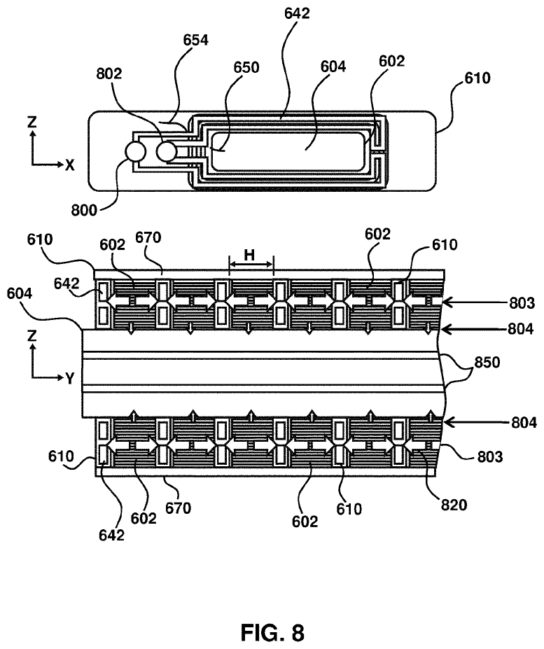

FIG. 8 illustrates cooling channels 642 (in the xz plane in this figure) in a cooling plate 610 connected to main inlet 800/outlet 802 channels (into/out of the page) traversing a length of armature 604 and/or a motor unit of a liner actuator (in the y-direction—again into/out of the page-two channels per straight conductor section in the x-direction are arbitrarily shown in this figure). Note that the cooling channel(s) may take any path, not necessarily straight paths along the length of the coil windings. Channel paths may be optimized to ensure every wind in the coil overlaps with cooling water at some point, for example. Cooling surfaces 803 (interfaces between surface wound electrical coils 602 and cooling plates 610) are shown (indicated by the larger arrows). Heat is transferred 820 from coils 602 to cooling plates 610 at these locations. Additional cooling surfaces 804 toward the inner winds of surface wound electrical coils 602 facing armature 604 are available because of the configuration of system 600 (FIG. 6). The inner winds of surface wound electrical coils 602 are in contact with armature 604, which can form an additional cooling surface. Heat is transferred 820 from surface wound electrical coils 602 to armature 604 at these locations across a coil (or copper) height H (for the outermost winds of a surface wound electrical coil 602, the thermal resistance of the armature may be >10× higher than the thermal resistance of winds adjacent to cooling plates 610). Armature 604 may include additional optional cooling channels 850 (two are arbitrarily shown here) to transport heat transferred from the inner coil surfaces to armature 604.

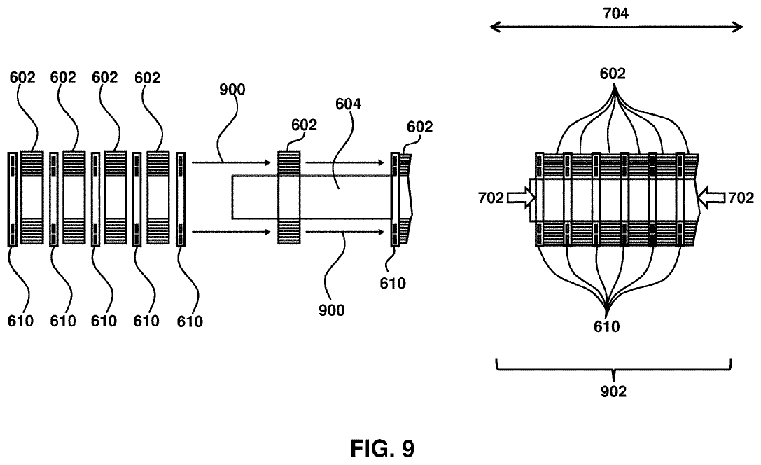

FIG. 9 illustrates how the plurality of surface wound electrical coils 602 and the plurality of cooling plates 610 are configured to be assembled 900 piece by piece, with alternating surface wound electrical coils 602 and cooling plates 610 coupled to each other to form cooling system 600. A surface wound electrical coil 602 and plate 610 stack 902 is configured to be mechanically preloaded in a moving direction of the linear actuator. FIG. 9 depicts an example assembly scheme, which comprises stacking cooling plates 610 and surface wound electrical coils 602 onto a common armature 604 and soldering (and testing) connections sequentially. The whole assembly can be put into compression and held by a tensioning rod, for example, and/or other methods. Omitting a potting layer while maintaining good thermal contact between electrical insulation on cooling plates 610 and surface wound electrical coils 602 is possible because of the controlled compression and/or other factors. This also enables easier disassembly and reuse of all working components of the forcer for servicing/refurbishing.

As shown in FIG. 9, cooing plates 610 only need to be as wide as a single surface wound electrical coil 602, and long enough to span a surface wound electrical coil 602 plus a footprint for cooling and electrical bus connections and interfacing. This results in needing smaller individual cooling plates 610, than are typically used in prior systems. In addition, as described above (FIG. 8), cooling plate 610 thickness no longer (compared to prior systems) limits the magnetic gap, which means cooling plates 610 can be thicker than what was typically used in prior systems (e.g., ~0.9 mm thickness). This facilitates cheaper and easier manufacturing, among other advantages.

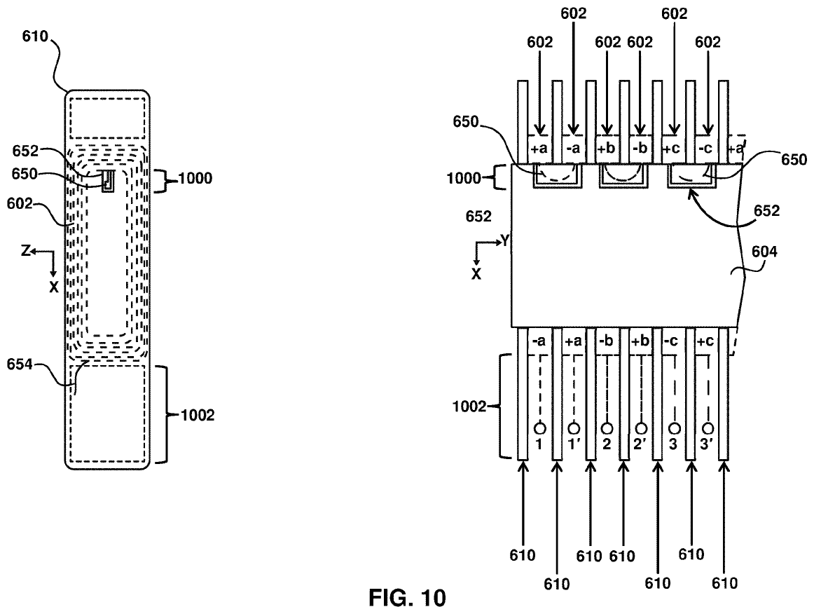

FIG. 10 illustrates regions 1000, 1002 of a surface wound electrical coil 602/plate 610 configured for routing electrical connections through volumes between cooling plates 610 and penetrating cooling plate 610 (e.g., xz in this example) cross sections (e.g., in the y direction in this example). Internal leads 650 (in region 1000) may have a soldered connection to an adjacent surface wound electrical coil 602 routed through a groove 652 or other orifice in armature 604. External leads 654 may be connected to another surface wound electrical coil 602 in series, a junction between parallel phases, or to an amplifier through a bus connection made in the (three dimensional) region 1002 beyond surface wound electrical coil 602 ends. The arrangement allows for relatively simple realization of distributed phase currents. Note: one main benefit of using a distributed phase current is to reduce spatial harmonics in a forcer's generated electro-motive force, and thus more efficiently use the available flux from the opposite side (mover or stator, e.g. Halbach magnet track) to generate thrust. The result should be a higher force density actuator with lower force ripple.

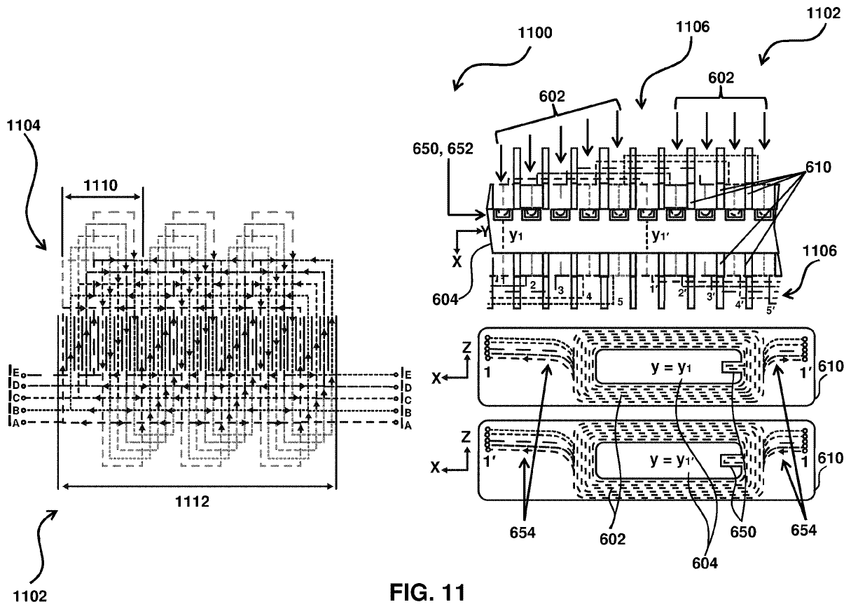

FIG. 11 illustrates an example three-phase forcer 1100 with a distributed current distribution 1102. Inner leads 650, outer leads 654, and/or the plurality of surface wound electrical coils 602 are configured such that distributed phase currents are achieved by overlapping windings 1104, 1106. A half-coil pairing may be used between cooling plates 610, for example. As shown in FIG. 11, realizing a distributed phase current generally requires overlapping the wiring, which requires extra volume and solution of a difficult 3D routing puzzle. An advantage of cooling system 600 (FIG. 6) is that one can realize distributed phase currents with flat wire coils without overlapping them in the magnetic gap, by simply allowing individual phases to connect to busses penetrating the motor volume along the drive direction of the motor (y-axis). Additionally, additional cooling plates 610 and/or a number of winds per phase can be selected as part of the inherent design freedom included with system 600. FIG. 11 illustrates one example five phase actuator 1110, and an actuator package 1112 having some number of actuators 1110 connected in series. An actuator is a single group of phases constituting one complete electrical cycle, (e.g. for a three phase actuator, one group of individual R, S, T phases). An actuator package or assembly might be multiple three phase actuators linked electrically (all R phases in parallel with one another, same for S, same for T), or simply several actuators packaged into one assembly mechanically.

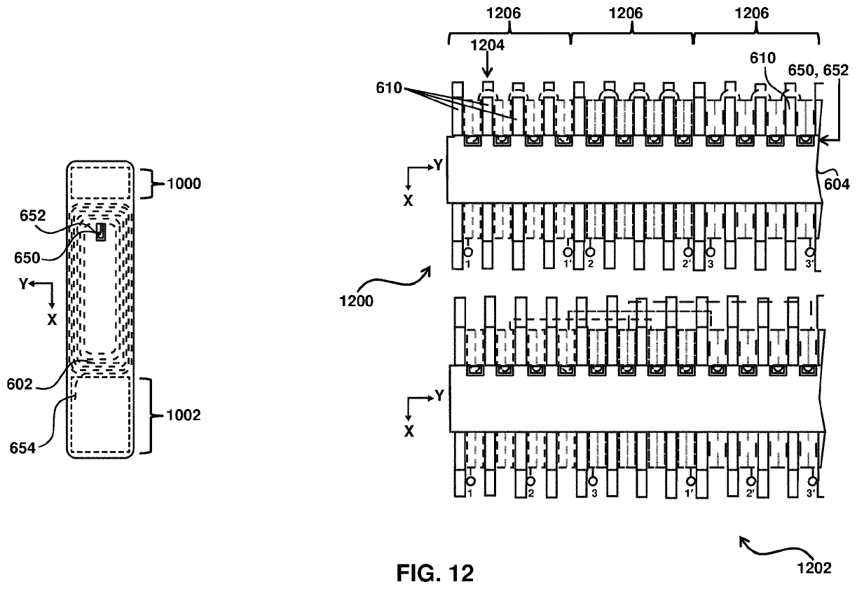

FIG. 12 illustrates example three-phase forcers with concentrated 1200 and distributed 1202 current distributions. Inner leads 650, outer leads 654, and/or the plurality of surface wound electrical coils 602 are configured such that concentrated 1200 phase currents are achieved using stacked monocoils 602 between cooling plates 610. FIG. 12 illustrates a half-coil pairing 1204 with five cooling plates 610 per phase 1206, though an arbitrary number half-coil pairs and cooling plates 610 per phase is possible. This preserves design freedom to adjust the number of turns per phase, and the number of cooling surfaces per phase so that optimal performance may be realized, and/or has other advantages.

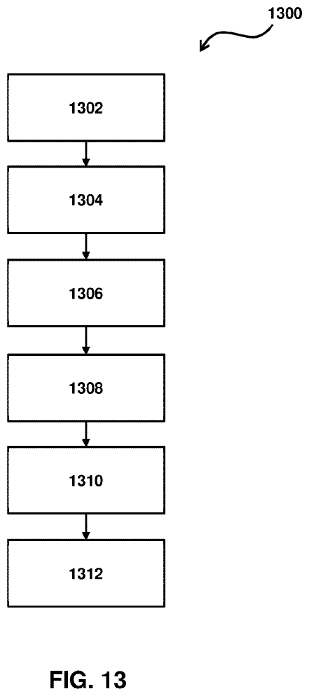

FIG. 13 illustrates a cooling method for a linear actuator. The linear actuator may be a Lorentz actuator or an iron core linear actuator with magnetic materials present in the armature with or without slots or magnetic teeth in the armature (as described above, these may also be known as slotted iron core LPMSMs (Linear Permanent Magnet Synchronous Motors), for example). Method 1300 may be performed with a cooling system, for example, as described herein. The cooling system and the linear actuator may form parts of a lithography apparatus, or a metrology apparatus configured for a semiconductor manufacturing process, and/or parts of other systems.

The operations of method 1300 presented below are intended to be illustrative. In some embodiments, method 1300 may be accomplished with one or more additional operations not described, and/or without one or more of the operations discussed. Additionally, the order in which the operations of method 1300 are illustrated in FIG. 13 and described below is not intended to be limiting.

At an operation 1302, a plurality of wound electrical coils are formed. The coils are configured to be energized to provide an electromagnetic force for the linear actuator. The plurality of wound electrical coils is configured to surround an armature of the linear actuator. The plurality of wound electrical coils may comprise surface wound flat wire coils or toroidal wound coils, for example. The plurality of wound electrical coils can be soldered to each other via inner leads routed through a groove in the armature. The plurality of wound electrical coils comprise outer leads configured to couple with another coil in series, a junction between parallel phases, or to an amplifier. The inner leads, the outer leads, and/or the plurality of wound electrical coils are configured such that distributed phase currents are achieved by overlapping windings. In some embodiments, the inner leads, the outer leads, and/or the plurality of wound electrical coils are configured such that concentrated phase currents are achieved using stacked coils between cooling plates. In some embodiments, operation 1302 is performed by a plurality of wound electrical coils the same as or similar to the plurality of wound electrical coils described above, and/or other components.

At an operation 1304, a plurality of cooling plates is formed and positioned in thermal contact with the plurality of wound electrical coils. The plurality of cooling plates is configured to cool the plurality of wound electrical coils. Individual plates of the plurality of cooling plates are configured to surround the armature and are positioned between adjacent individual coils such that the plurality of wound electrical coils and the plurality of cooling plates form an alternating series of plates and coils along a length of the armature. The length comprises a portion of, or a full length of the armature. In some embodiments, the plurality of cooling plates have generally rectangular cross sections with one or more cooling channels configured to carry coolant formed therein. In some embodiments, operation 1304 is performed by a plurality of cooling plates the same as or similar to the plurality of cooling plates described above, and/or other components.

At operation 1306, the plurality of wound electrical coils and the plurality of cooling plates are oriented in planes generally perpendicular to the length of the armature. At an operation 1308, the plurality of wound electrical coils and the plurality of cooling plates is assembled piece by piece, with alternating wound electrical coils and cooling plates coupled to each other to form the cooling system. At operation 1310, the plurality of cooling plates are coupled together such that the one or more cooling channels carry the coolant to cool the plurality of wound electrical coils along the length of the armature. In some embodiments, operations 1306-1310 are performed by a plurality of wound electrical coils and/or a plurality of cooling plates similar to and/or the same as the coils and/or cooling plates described above, and/or other components.

In some embodiments, a generally perpendicular orientation of the plurality of wound electrical coils and the plurality of cooling plates relative to the length of the armature, and/or a separate piece by piece nature of the plurality of wound electrical coils and the plurality of cooling plates, is configured to reduce shear forces on mechanical fasteners and/or adhesives joining any two wound electrical coils and/or cooling plates along the length of the armature compared to a parallel orientation and/or a unitary structure of the plurality of wound electrical coils and the plurality of cooling plates. In some embodiments, coil and plate stacks are configured to be mechanically preloaded in a moving direction of the linear actuator to reduce and/or eliminate a need for glue and/or potting between coils and a coil housing (though this may be optionally included in the system as shown in FIG. 6), to couple the coils to the coolplates during operation (FIG. 7 shows reaction forces 710).

In some embodiments, the generally perpendicular orientation of the plurality of cooling plates relative to the length of the armature is configured to reduce a distance between magnets of the linear actuator and a ferromagnetic backiron compared to a parallel orientation of the cooling plates. In some embodiments, the plurality of cooling plates comprise regions having one or more cooling channels and/or electrical routing in plane, regions for bus routing in a normal direction, and/or regions for mechanical coupling to the armature, another plate, and/or a coil.

At an operation 1312, insulation and/or adhesive may be positioned between the plurality of wound electrical coils and the plurality of cooling plates. The insulation may comprise Kapton, a ceramic sheet, a nylon sheet, a Teflon sheet, and/or any another corona resistant polyimide. In general, any material that could serve as an electrical insulator between the coil windings and the metal (as one example material) cool plate may comprise the insulation. In some embodiments, the cooling plates themselves may be an insulting ceramic material and there may be some material between the cooling plates and the coil windings configured for thermal coupling. Operation 1312 may also include providing canning surfaces configured to enclose the plurality of wound electrical coils, the plurality of cooling plates, and the armature. In some embodiments, operation 1312 is performed by the insulation, adhesive, and/or canning surfaces described herein, and/or other components.

Various embodiments of the present systems and methods are disclosed in the subsequent list of numbered clauses:
1. A cooling system for a linear actuator, the system comprising: a plurality of wound electrical coils configured to be energized to provide an electromagnetic force for the linear actuator, the plurality of wound electrical coils configured to surround an armature of the linear actuator; and a plurality of cooling plates in thermal contact with the plurality of wound electrical coils and configured to cool the plurality of wound electrical coils, wherein individual plates of the plurality of cooling plates are configured to surround the armature and are positioned between adjacent individual coils such that the plurality of wound electrical coils and the plurality of cooling plates form an alternating series of plates and coils along a length of the armature.
2. The system of clause 1, wherein the plurality of wound electrical coils and the plurality of cooling plates are configured to be oriented in planes generally perpendicular to the length of the armature.
3. The system of any of the previous clauses, wherein the plurality of wound electrical coils and the plurality of cooling plates are configured to be assembled piece by piece, with alternating wound electrical coils and cooling plates coupled to each other to form the cooling system.
4. The system of any of the previous clauses, wherein a generally perpendicular orientation of the plurality of wound electrical coils and the plurality of cooling plates relative to the length of the armature, and/or a separate piece by piece nature of the plurality of wound electrical coils and the plurality of cooling plates, is configured to reduce shear forces on mechanical fasteners and/or adhesives joining any two wound electrical coils and/or cooling plates along the length of the armature compared to a parallel orientation and/or a unitary structure of the plurality of wound electrical coils and the plurality of cooling plates.
5. The system of any of the previous clauses, wherein a generally perpendicular orientation of the plurality of cooling plates relative to the length of the armature is configured to reduce a distance between magnets of the linear actuator and a ferromagnetic backiron compared to a parallel orientation of the cooling plates.
6. The system of any of the previous clauses, wherein the plurality of cooling plates have generally rectangular cross sections with one or more cooling channels configured to carry coolant formed therein.
7. The system of any of the previous clauses, wherein the plurality of cooling plates are configured to be coupled together such that the one or more cooling channels carry the coolant to cool the plurality of wound electrical coils along the length of the armature.
8. The system of any of any of the previous clauses, wherein the plurality of cooling plates comprise regions having one or more cooling channels and/or electrical routing in plane, regions for bus routing in a normal direction, and/or regions for mechanical coupling to the armature, another plate, and/or a coil.
9. The system of any of any of the previous clauses, wherein the plurality of wound electrical coils are configured to be soldered to each other via inner leads routed through a groove in the armature.
10. The system of any of the previous clauses, wherein the plurality of wound electrical coils comprise outer leads configured to couple with another coil in series, a junction between parallel phases, or to an amplifier.
11. The system of any of the previous clauses, wherein the inner leads, the outer leads, and/or the plurality of wound electrical coils are configured such that distributed phase currents are achieved by overlapping windings.
12. The system of any of the previous clauses, wherein the inner leads, the outer leads, and/or the plurality of wound electrical coils are configured such that concentrated phase currents are achieved using stacked coils between cooling plates.
13. The system of any of any of the previous clauses, further comprising insulation and/or adhesive positioned between the plurality of wound electrical coils and the plurality of cooling plates.
14. The system of any of the previous clauses, wherein the insulation comprises Kapton, a ceramic sheet, a nylon sheet, a Teflon sheet, or another corona resistant polyimide.
15. The system of any of the previous clauses, wherein the plurality of wound electrical coils comprise surface wound flat wire coils or toroidal wound coils.
16. The system of any of the previous clauses, wherein coil and plate stacks are configured to be mechanically preloaded in a moving direction of the linear actuator to eliminate a need for glue and/or potting between coils and a coil housing to couple the coils to the cool plates during operation.
17. The system of any of the previous clauses, further comprising canning surfaces configured to enclose the plurality of wound electrical coils, the plurality of cooling plates, and the armature.
18. The system of any of the previous clauses, wherein the linear actuator is a Lorentz actuator, or a linear actuator with magnetic materials present in its armature, with our without slots or magnetic teeth in the armature.
19. The system of any of the previous clauses, wherein the length comprises a portion of, or a full length of the armature.
20. The system of any of the previous clauses, wherein the cooling system and the linear actuator form parts of a lithography apparatus or a metrology apparatus configured for a semiconductor manufacturing process.
21. A cooling method for a linear actuator, the method comprising: forming a plurality of wound electrical coils configured to be energized to provide an electromagnetic force for the linear actuator, the plurality of wound electrical coils configured to surround an armature of the linear actuator; and forming a plurality of cooling plates and positioning them in thermal contact with the plurality of wound electrical coils, the plurality of cooling plates configured to cool the plurality of wound electrical coils, wherein individual plates of the plurality of cooling plates are configured to surround the armature and are positioned between adjacent individual coils such that the plurality of wound electrical coils and the plurality of cooling plates form an alternating series of plates and coils along a length of the armature.
22. The method of clause 21, further comprising orienting the plurality of wound electrical coils and the plurality of cooling plates in planes generally perpendicular to the length of the armature.
23. The method of any of the previous clauses, further comprising assembling the plurality of wound electrical coils and the plurality of cooling plates piece by piece, with alternating wound electrical coils and cooling plates coupled to each other to form the cooling system.
24. The method of any of the previous clauses, wherein a generally perpendicular orientation of the plurality of wound electrical coils and the plurality of cooling plates relative to the length of the armature, and/or a separate piece by piece nature of the plurality of wound electrical coils and the plurality of cooling plates, is configured to reduce shear forces on mechanical fasteners and/or adhesives joining any two wound electrical coils and/or cooling plates along the length of the armature compared to a parallel orientation and/or a unitary structure of the plurality of wound electrical coils and the plurality of cooling plates.
25. The method of any of the previous clauses, wherein a generally perpendicular orientation of the plurality of cooling plates relative to the length of the armature is configured to reduce a distance between magnets of the linear actuator and a ferromagnetic backiron compared to a parallel orientation of the cooling plates.
26. The method of any of the previous clauses, wherein the plurality of cooling plates have generally rectangular cross sections with one or more cooling channels configured to carry coolant formed therein.
27. The method of any of the previous clauses, further comprising coupling the plurality of cooling plates together such that the one or more cooling channels carry the coolant to cool the plurality of wound electrical coils along the length of the armature.
28. The method of any of the previous clauses, wherein the plurality of cooling plates comprise regions having one or more cooling channels and/or electrical routing in plane, regions for bus routing in a normal direction, and/or regions for mechanical coupling to the armature, another plate, and/or a coil.
29. The method of any of the previous clauses, further comprising soldering the plurality of wound electrical coils to each other via inner leads routed through a groove in the armature.
30. The method of any of clauses 21-29, wherein the plurality of wound electrical coils comprise outer leads configured to couple with another coil in series, a junction between parallel phases, or to an amplifier.
31. The method of any of the previous clauses, wherein the inner leads, the outer leads, and/or the plurality of wound electrical coils are configured such that distributed phase currents are achieved by overlapping windings.
32. The method of any of the previous clauses, wherein the inner leads, the outer leads, and/or the plurality of wound electrical coils are configured such that concentrated phase currents are achieved using stacked coils between cooling plates.
33. The method of any of the previous clauses, further comprising positioning insulation and/or adhesive between the plurality of wound electrical coils and the plurality of cooling plates.
34. The method of any of the previous clauses, wherein the insulation comprises Kapton, a ceramic sheet, a nylon sheet, a Teflon sheet, or another corona resistant polyimide.
35. The method of any of the previous clauses, wherein the plurality of wound electrical coils comprise surface wound flat wire coils or toroidal wound coils.
36. The method of any of the previous clauses, wherein coil and plate stacks are configured to be mechanically preloaded in a moving direction of the linear actuator to eliminate a need for glue and/or potting between coils and a coil housing to couple the coils to the cool plates during operation.
37. The method of any of the previous clauses, further comprising providing canning surfaces configured to enclose the plurality of wound electrical coils, the plurality of cooling plates, and the armature.
38. The method of any of the previous clauses, wherein the linear actuator is a Lorentz actuator, or a linear actuator with magnetic materials present in its armature, with our without slots or magnetic teeth in the armature.
39. The method of any of the previous clauses, wherein the length comprises a portion of, or a full length of the armature.
40. The method of any of the previous clauses, wherein the cooling system and the linear actuator form parts of a lithography apparatus or a metrology apparatus configured for a semiconductor manufacturing process.
41. A lithography apparatus configured for a semiconductor manufacturing process, comprising: a linear actuator; and a cooling system for the linear actuator, the cooling system comprising: a plurality of wound electrical coils configured to be energized to provide an electromagnetic force for the linear actuator, the plurality of wound electrical coils configured to surround an armature of the linear actuator; and a plurality of cooling plates in thermal contact with the plurality of wound electrical coils and configured to cool the plurality of wound electrical coils, wherein individual plates of the plurality of cooling plates are configured to surround the armature and are positioned between adjacent individual coils such that the plurality of wound electrical coils and the plurality of cooling plates form an alternating series of plates and coils along a length of the armature.

While the concepts disclosed herein may be used for a linear actuator associated with wafer manufacturing on a substrate such as a silicon wafer, it shall be understood that the disclosed concepts may be used with any type of manufacturing system that may include a linear actuator, e.g., those used for manufacturing on substrates other than silicon wafers. In addition, the combination and sub-combinations of disclosed elements may comprise separate embodiments. For example, the cooling system, and an associated lithography apparatus that includes the cooling system may comprise separate embodiments, and/or these features may be used together in the same embodiment.

The descriptions above are intended to be illustrative, not limiting. Thus, it will be apparent to one skilled in the art that modifications may be made as described without departing from the scope of the claims set out below.

1. A cooling system for a linear actuator, the system comprising:
a plurality of electrical coils configured to be energized to provide an electromagnetic force for the linear actuator, the plurality of electrical coils configured to surround an armature of the linear actuator; and
a plurality of cooling plates in thermal contact with the plurality of electrical coils and configured to cool the plurality of electrical coils, wherein individual plates of the plurality of cooling plates are configured to surround the armature and are positioned between adjacent individual electrical coils such that the plurality of electrical coils and the plurality of cooling plates form an alternating series of plates and coils along a length of the armature.

2. The system of claim 1, wherein the plurality of electrical coils and the plurality of cooling plates are configured to be oriented in planes generally perpendicular to the length of the armature.

3. The system of claim 1, wherein the plurality of electrical coils and the plurality of cooling plates are configured to be assembled piece by piece, with alternating electrical coils and cooling plates coupled to each other to form the cooling system.

4. The system of claim 1, wherein a generally perpendicular orientation of the plurality of electrical coils and the plurality of cooling plates relative to the length of the armature, and/or a separate piece by piece nature of the plurality of electrical coils and the plurality of cooling plates, is configured to reduce shear forces on mechanical fasteners and/or adhesives joining any two electrical coils and/or cooling plates along the length of the armature compared to a parallel orientation and/or a unitary structure of the plurality of electrical coils and the plurality of cooling plates.

5. The system of claim 1, wherein a generally perpendicular orientation of the plurality of cooling plates relative to the length of the armature is configured to reduce a distance between magnets of the linear actuator and a ferromagnetic backiron compared to a parallel orientation of the cooling plates.

6. The system of claim 1, wherein the cooling plates have generally rectangular cross sections with one or more cooling channels configured to carry coolant formed therein, and wherein the cooling plates are configured to be coupled together such that the one or more cooling channels carry the coolant to cool the plurality of electrical coils along the length of the armature.

7. The system of claim 1, wherein the cooling plates comprise regions having one or more cooling channels and/or electrical routing in plane, regions for bus routing in a normal direction, and/or regions for mechanical coupling to the armature, another plate, and/or a coil.

8. The system of claim 1, wherein:
the electrical coils are configured to be soldered to each other via inner leads routed through a groove in the armature; and
the inner leads, outer leads, and/or the plurality of electrical coils are configured such that distributed phase currents are achieved by overlapping windings; and
the inner leads, the outer leads, and/or the plurality of electrical coils are configured such that concentrated phase currents are achieved using stacked coils between cooling plates.

9. The system of claim 1, wherein:
the electrical coils comprise outer leads configured to couple with another coil in series, a junction between parallel phases, or to an amplifier;
inner leads, the outer leads, and/or the plurality of electrical coils are configured such that distributed phase currents are achieved by overlapping windings; and
the inner leads, the outer leads, and/or the plurality of electrical coils are configured such that concentrated phase currents are achieved using stacked coils between cooling plates.

10. The system of claim 1, further comprising insulation and/or adhesive positioned between the plurality of electrical coils and the plurality of cooling plates, wherein the insulation comprises Kapton polyimide, a ceramic sheet, a nylon sheet, a Teflon sheet, or another corona resistant polyimide.

11. The system of claim 1, wherein:
the electrical coils comprise surface wound flat wire coils or toroidal wound coils; and
coil and plate stacks are configured to be mechanically preloaded in a moving direction of the linear actuator to eliminate a need for glue and/or potting between coils and a coil housing to couple the coils to the cooling plates during operation.

12. The system of claim 1, further comprising canning surfaces configured to enclose the plurality of electrical coils, the plurality of cooling plates, and the armature.

13. The system of claim 1, wherein:
the linear actuator is a Lorentz actuator, or a linear actuator with magnetic materials present in its armature;
the length of the linear actuator comprises a portion of, or a full length of the armature; and
the cooling system and the linear actuator form parts of a lithography apparatus or a metrology apparatus configured for a semiconductor manufacturing process.

14. A cooling method for a linear actuator, the method comprising:
forming a plurality of electrical coils configured to be energized to provide an electromagnetic force for the linear actuator, the plurality of electrical coils configured to surround an armature of the linear actuator; and
forming a plurality of cooling plates and positioning them in thermal contact with the plurality of electrical coils, the plurality of cooling plates configured to cool the plurality of electrical coils, wherein individual plates of the plurality of cooling plates are configured to surround the armature and are positioned between adjacent individual coils such that the plurality of electrical coils and the plurality of cooling plates form an alternating series of plates and coils along a length of the armature.

15. A lithography or metrology apparatus configured for a semiconductor manufacturing process, the apparatus comprising:
a linear actuator comprising a plurality of electrical coils configured to be energized to provide an electromagnetic force for the linear actuator to move an object in the apparatus, the plurality of electrical coils configured to surround an armature of the linear actuator; and
a cooling system for the linear actuator, the cooling system comprising a plurality of cooling plates in thermal contact with the plurality of electrical coils and configured to cool the plurality of electrical coils, wherein individual plates of the plurality of cooling plates are configured to surround the armature and are positioned between adjacent individual electrical coils such that the plurality of electrical coils and the plurality of cooling plates form an alternating series of plates and coils along a length of the armature.

16. The apparatus of claim 15, wherein the plurality of electrical coils and the plurality of cooling plates are configured to be oriented in planes generally perpendicular to the length of the armature.

17. The apparatus of claim 15, wherein the cooling plates have generally rectangular cross sections with one or more cooling channels configured to carry coolant formed therein, and wherein the cooling plates are configured to be coupled together such that the one or more cooling channels carry the coolant to cool the plurality of electrical coils along the length of the armature.

18. The apparatus of claim 15, wherein the cooling plates comprise regions having one or more cooling channels and/or electrical routing in plane, regions for bus routing in a normal direction, and/or regions for mechanical coupling to the armature, another plate, and/or a coil.

19. The apparatus of claim 15, wherein:
the electrical coils are configured to be soldered to each other via inner leads routed through a groove in the armature and/or the electrical coils comprise outer leads configured to couple with another coil in series, a junction between parallel phases, or to an amplifier; and
the inner leads, the outer leads, and/or the plurality of electrical coils are configured such that distributed phase currents are achieved by overlapping windings; and
the inner leads, the outer leads, and/or the plurality of electrical coils are configured such that concentrated phase currents are achieved using stacked coils between cooling plates.

20. The apparatus of claim 15, wherein:
the electrical coils comprise surface wound flat wire coils or toroidal wound coils; and
coil and plate stacks are configured to be mechanically preloaded in a moving direction of the linear actuator to eliminate a need for glue and/or potting between coils and a coil housing to couple the coils to the cooling plates during operation.
